(19) United States
(12) Patent Application Publication
(10) Pub. No.: US 2026/0366143 A1
(43) Pub. Date: Nov. 19, 2026

(54) SUBSTRATE PROCESSING METHOD

(71) Applicant: ASM IP Holding B.V., Almere (NL)

(72) Inventors: Jereld Lee Winkler, Gilbert, AZ (US); Ren-Jie Chang, Chandler, AZ (US); Fu Tang, Gilbert, AZ (US); Rishabh Rastogi, Chandler, AZ (US); Charles Dezelah, Helsinki (FI); Eric James Shero, Phoenix, AZ (US)

(21) Appl. No.: 19/672,962

(22) Filed: May 11, 2026

Related U.S. Application Data
(60) Provisional application No. 63/805,507, filed on May 14, 2025.

(51) Int. Cl. C23C 16/04; C23C 16/40; C23C 16/455; C23C 16/46; H10P 14/60; H10P 14/69

(52) U.S. Cl. CPC C23C 16/045; C23C 16/403; C23C 16/45553; C23C 16/46; H10P 14/6339; H10P 14/668; H10P 14/6908

(57) ABSTRACT

A method can comprise providing a substrate into a reaction chamber, wherein the substrate comprises a vertical gap and a horizontal gap; heating the substrate within the reaction chamber; providing a first precursor compound comprising a metal-oxygen bond, wherein the first precursor compound is in the form of an oligomer; and/or providing a reactant compound to the reaction chamber, wherein the reactant compound comprises oxygen. Heating the substrate can cause decomposition of the oligomer to a decomposed compound and migration of the decomposed compound into the vertical gap and the horizontal gap. The decomposed compound can comprise the metal-oxygen bond.

### CROSS-REFERENCE TO RELATED APPLICATIONS

This application is a nonprovisional of, and claims priority to and the benefit of, U.S. Provisional Patent Application No. 63/805,507, filed May 14, 2025 and entitled “SUBSTRATE PROCESSING METHOD,” which is hereby incorporated by reference herein.

### FIELD

The present disclosure relates to methods of forming a semiconductor structure, and, in particular, to a method of filling a gap feature(s) on a substrate.

### BACKGROUND

Semiconductor devices generally include patterned features that are used to form (e.g., 3D) transistors, ribbons, gate-all-around transistors, and the like. During formation of such devices, it is often desirable to fill a gap within or between various features. As feature sizes on substrates are reduced and/or complexity of the features increases, it can become more difficult to fill gaps with material having desired properties.

There are various profile control methods in gap fill technology. General gap fill technologies include depositing material using chemical vapor deposition (CVD) or atomic layer deposition (ALD) processes. While some techniques can work well for some applications, desired gap fill conformality and/or gap fill without a seam or void can be difficult. Accordingly, improved gap fill methods are generally desired.

Any discussion of problems and solutions has been included in this disclosure solely for the purposes of providing a context for the present disclosure, and should not be taken as an admission that any or all of the discussion was known at the time the disclosure was made.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In accordance with various embodiments of the disclosure, a method is provided, the method including: providing a substrate into a reaction chamber, the substrate including a vertical gap and a horizontal gap; heating the substrate within the reaction chamber; providing a first precursor compound including a metal-oxygen bond, the first precursor compound being in the form of an oligomer; and providing a reactant compound to the reaction chamber, the reactant compound including oxygen, heating the substrate causing decomposition of the oligomer to a decomposed compound and migration of the decomposed compound into the vertical gap and the horizontal gap, the decomposed compound including the metal-oxygen bond.

In some embodiments, the method further includes forming a metal oxide layer on the substrate.

In some embodiments, the metal oxide layer is substantially seamless.

In some embodiments, a metal element of the metal oxide layer includes at least one of aluminum, titanium, zirconium, or tantalum.

In some embodiments, the first precursor compound has a chemical formula of MₓR_{y}(OR′)_{z}, wherein M is the metal, wherein y+z=3x, and x is the number of units in the oligomer.

In some embodiments, the first precursor compound includes dimethylaluminum isopropoxide, and the dimethylaluminum isopropoxide is in the form of a dimer before the decomposition.

In some embodiments, the metal oxide layer includes aluminum oxide.

In some embodiments, the first precursor compound further includes an alkyl group bonded to the oxygen.

In some embodiments, the migration of the decomposed compound into the horizontal gap occurs at least partially via molecular flow.

In some embodiments, the substrate is heated to a temperature greater than 250 °C during the heating step.

In some embodiments, the substrate is heated to a temperature between 250 °C and 400 °C during the heating step.

In accordance with various embodiments of the disclosure, a method is provided, the method including: heating a substrate within a reaction chamber, the substrate including a vertical gap and a horizontal gap; pulsing a first precursor compound into the reaction chamber, the first precursor compound including a metal-oxygen bond, and the first precursor compound being in the form of an oligomer, heating the substrate including heating to a temperature above a decomposition temperature of the oligomer to form a decomposed compound; pulsing a reactant compound into the reaction chamber, the reactant compound including oxygen, decomposition of the oligomer to the decomposed compound causing migration of the decomposed compound into the vertical gap and the horizontal gap; and forming a substantially seamless metal oxide layer on the substrate.

In some embodiments, the first precursor compound further includes an alkyl group bonded to the oxygen.

In some embodiments, a metal element of the metal oxide layer includes at least one of aluminum, titanium, zirconium, or tantalum.

In some embodiments, the first precursor compound includes dimethylaluminum isopropoxide.

In some embodiments, the reactant compound includes water.

In some embodiments, heating the substrate includes heating the substrate to a temperature greater than 250 °C.

In accordance with various embodiments of the disclosure, a method is provided, the method including: heating a substrate within a reaction chamber to a temperature greater than 250 °C, the substrate including a vertical gap and a horizontal gap; providing a first precursor compound into the reaction chamber, the first precursor compound including a metal-oxygen bond, and the first precursor compound being in the form of an oligomer; providing a reactant compound into the reaction chamber, the reactant compound including water; forming a flowable compound including a metal hydroxide and the metal-oxygen bond in response to providing the reactant compound, the flowable compound migrating into the vertical gap and the horizontal gap; and forming a substantially seamless metal oxide layer on the substrate.

In some embodiments, the oligomer decomposes to a decomposed compound in response to the first precursor compound contacting the heated substrate.

In some embodiments, the first precursor compound includes dimethylaluminum isopropoxide.

For the purpose of summarizing the disclosure and the advantages achieved over the prior art, certain objects and advantages of the disclosure have been described herein above. Of course, it is to be understood that not necessarily all such objects or advantages may be achieved in accordance with any particular example of the disclosure. Thus, for example, those skilled in the art will recognize that the examples disclosed herein can be carried out in a manner that achieves or optimizes one advantage or group of advantages as taught or suggested herein without necessarily achieving other objects or advantages as may be taught or suggested herein.

All of these examples are intended to be within the scope of the disclosure. These and other examples will become readily apparent to those skilled in the art from the following detailed description of certain examples having reference to the attached figures, the disclosure not being limited to any particular example(s) discussed.

### BRIEF DESCRIPTION OF THE DRAWING FIGURES

While the specification concludes with claims particularly pointing out and distinctly claiming what are regarded as examples of the disclosure, the advantages of examples of the disclosure may be more readily ascertained from the description of certain examples when read in conjunction with the accompanying drawings. Elements with the like element numbering throughout the figures are intended to be the same.

FIG. 1 is a schematic diagram of an exemplary reactor system, in accordance with various examples.

FIG. 2A is a schematic view of a semiconductor structure, in accordance with various examples.

FIG. 2B is a close-up view of a portion of the semiconductor structure of FIG. 2A, in accordance with various examples.

FIG. 3A is a schematic view of another semiconductor structure, in accordance with various examples.

FIG. 3B is a close-up view of a portion of the semiconductor structure of FIG. 3A, in accordance with various examples.

FIG. 4A is a schematic view of another semiconductor structure, in accordance with various examples.

FIG. 4B is a close-up view of a portion of the semiconductor structure of FIG. 4A, in accordance with various examples.

FIG. 5 depicts a method of depositing material on a substrate, in accordance with various examples.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of examples of methods, structures, devices, and systems provided below is merely exemplary and is intended for purposes of illustration only—the following description is not intended to limit the scope of the disclosure or the claims. Moreover, recitation of multiple examples having stated features is not intended to exclude other examples having additional features or other examples incorporating different combinations of the stated features. For example, various examples are set forth as embodiments and may be recited in the dependent claims. Unless otherwise noted, the examples or components thereof may be combined or may be applied separately from each other. Methods may include the disclosed steps in any suitable and/or desired order or combination. The illustrations presented herein are not meant to be actual views of any particular material, apparatus, structure, or device, but are merely representations that are used to describe examples of the disclosure.

As used herein, the term “and/or” includes any and all combinations of one or more of the associated listed items. Unless otherwise noted, expressions such as “at least one of,” when preceding a list of elements, modify the entire list of elements and do not necessarily modify the individual elements of the list.

As used herein, the terms “includes,” “comprises,” “including,” and/or “comprising” specify the presence of stated features, integers, steps, processes, members, components, and/or groups thereof, and do not preclude the presence or addition of one or more other features, integers, steps, processes, members, components, and/or groups thereof. In this disclosure, any defined meanings do not necessarily exclude ordinary and customary meanings in some examples.

As used herein, the term “substrate” may refer to any underlying material or materials, including any underlying material or materials that may be modified, or upon which a device, a circuit, or a film or layer may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride, and/or silicon carbide.

As used herein, the term “atomic layer deposition” (ALD) may refer to a vapor deposition process in which deposition cycles, preferably a plurality of consecutive deposition cycles, are conducted in a process chamber. Typically, during each cycle the precursor is chemisorbed to a deposition surface (e.g., a substrate surface or a previously deposited underlying surface such as material from a previous ALD cycle), forming a monolayer or sub-monolayer that does not readily react with additional precursor (i.e., a self-limiting reaction). Thereafter, if necessary, a reactant (e.g., another precursor or reaction gas) may subsequently be introduced into the process chamber for use in converting the chemisorbed precursor to the desired material on the deposition surface. Typically, this reactant is capable of further reaction with the precursor. Further, purging steps may also be utilized during each cycle to remove excess precursor from the process chamber and/or remove excess reactant and/or reaction byproducts from the process chamber after conversion of the chemisorbed precursor. Further, the term “atomic layer deposition,” as used herein, is also meant to include processes designated by related terms such as, “chemical vapor atomic layer deposition” when performed with alternating pulses of precursor composition(s), reactive gas, and purge (e.g., inert carrier) gas.

As used herein, the term “chemical vapor deposition” (CVD) may refer to any process wherein a substrate is exposed to one or more precursors, which react and/or decompose on a substrate surface to produce a desired deposition.

In some examples, “film” refers to a layer extending in a direction perpendicular to a thickness direction. In some examples, “layer” refers to a material having a certain thickness formed on a surface and can be a synonym of a film or a non-film structure. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequence, and/or functions or purposes of the adjacent films or layers. The layer or film can be continuous—or not. Further, a single film or layer can be formed using one or more deposition cycles and/or one or more deposition and treatment cycles.

As used herein, a “precursor” can refer to a compound that participates in a chemical reaction to form another compound or element, wherein a portion of the precursor (an element or group within the precursor) is incorporated into the compound or element that results from the chemical reaction. The compound or element that results from the chemical reaction may be a layer and/or a film that is formed on a surface of a substrate.

As used herein, a “reactant” can refer to a compound that participates in a chemical reaction to form another compound or element. In some instances, a reactant can be a precursor.

In this disclosure, any two numbers of a variable can constitute a workable range of the variable, any ranges indicated may include or exclude the endpoints, and all ranges and ratio limits disclosed herein may be combined. Additionally, any values of variables indicated (regardless of whether they are indicated with “about” or not) may refer to precise values or approximate values and include equivalents, and may refer to average, median, representative, majority, etc. in some examples (e.g., “about” can refer to plus or minus 10% of the subject value). Unless specifically stated otherwise, references to “a,” “an,” and/or “the” may include one or more than one, and references to an item in the singular may also include the item in the plural. When referring to components of systems discussed herein, the term “coupled” refers to direct coupling or indirect coupling with other intervening elements, as appropriate. Unless otherwise indicated, the terms “first,” “second,” etc., and/or “primary,” “secondary,” etc., are used herein merely as labels, and are not intended to impose ordinal, positional, or hierarchical requirements on the items to which these terms refer. Moreover, reference to, e.g., a “second” item does not require or preclude the existence of, e.g., a “first” or lower-numbered item, and/or, e.g., a “third” or higher-numbered item. Further, reference to, e.g., a “first” item and a “second” item does not mean that there are no intervening items, and such intervening items may be present.

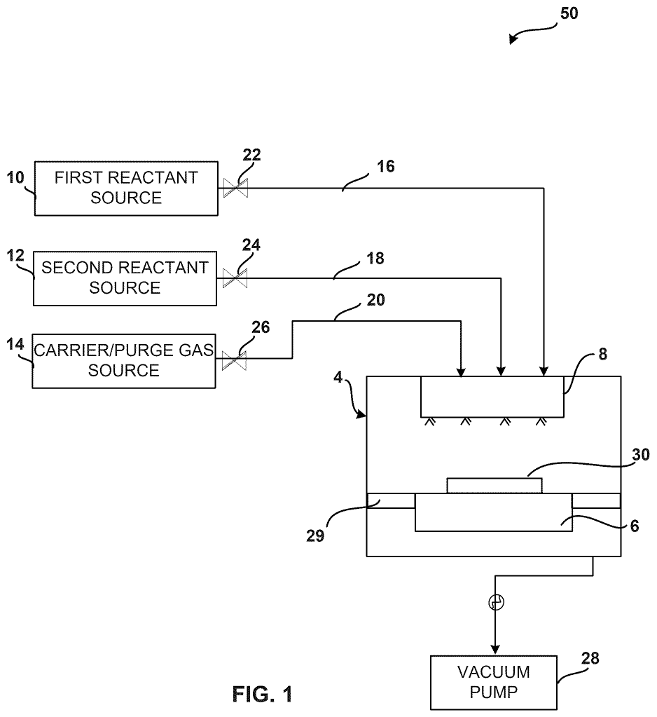

Reactor systems used for ALD, CVD, and/or the like, may be used for a variety of applications, including depositing and etching materials on a substrate surface. In various examples, with reference to FIG. 1, a reactor system 50 may comprise a reaction chamber 4, a susceptor 6 to hold a substrate 30 during processing, a fluid distribution system 8 (e.g., a showerhead) to distribute one or more reactants and/or precursors to a surface of substrate 30, one or more reactant sources 10, 12, and/or a carrier and/or purge gas source 14, fluidly coupled to reaction chamber 4 via lines 16-20, and/or valves or controllers 22-26. System 50 may also comprise a vacuum source 28 fluidly coupled to the reaction chamber 4. Sealing members 29 may separate (e.g., at least partially separate fluidly) portions of a volume within reaction chamber 4.

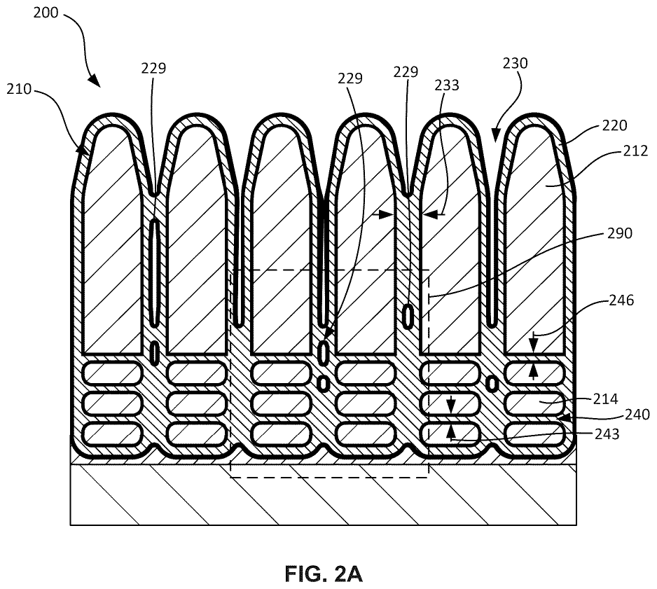

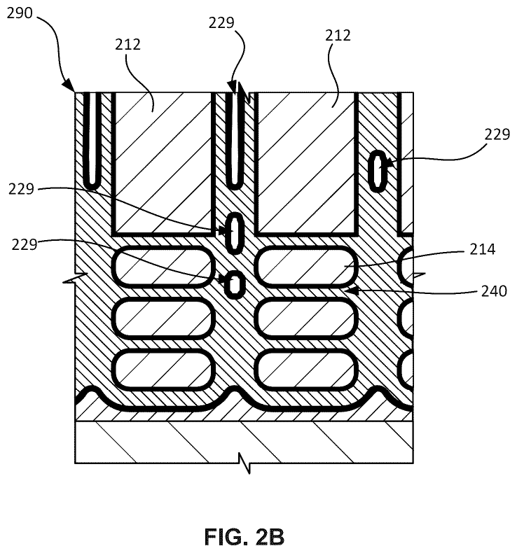

FIGS. 2A and 2B depict a schematic diagram of a portion of a semiconductor structure 200. The semiconductor structure 200 includes a substrate 210 and a material 220 disposed therein and thereon. Substrate 210 can comprise vertical posts 212 and/or horizontal ribbons 214. Substrate 210 can comprise a recess or vertical gaps 230 (e.g., vertically between vertical posts 212 and/or horizontal ribbons 214). Substrate 210 can comprise a horizontal gap(s) 240 between ribbons 214.

Vertical gaps 230 and horizontal gaps 240 can have any suitable dimensions. For example, vertical gaps 230 can have a dimension (e.g., width or thickness) 233 of 10-30 nanometers (nm), 10-20 nm, or 15-20 nm. As another example, horizontal gaps 240 can have a dimension (e.g., height or thickness) 243 of 5-20 nm, 5-15 nm, or about 5 or 10 nm (e.g., a horizontal gap 240 can have a dimension 243 of about 10 nm, or a dimension 246 of about 5 or 6 nm). “About” in this context means plus or minus 1, 2, or 3 nm. Vertical gaps 230 and horizontal gaps 240 can comprise any suitable aspect ratio. For example, vertical gaps 230 can have aspect ratios ranging from 7:1 to 12:1, and/or horizontal gaps 240 can have aspect ratios ranging from 2:1 to 5:1.

In various examples, material 220 can be deposited in vertical posts 212 and/or ribbons 214 in response to a deposition process. Material 220 can comprise a metal oxide. The metal oxide can comprise any suitable material and/or compound, for example, aluminum oxide, tantalum oxide, zirconium oxide, and/or titanium oxide, any of which may or may not be stoichiometric. Seams and/or voids 229 can be formed in material 220 during deposition of material 220. For example, a substantially conformal process can result in deposition of material 220 on imperfections on substrate 210 and/or accumulation at various portions, resulting in areas of material 220 pinching off to form voids 229. Deposition processes conducted at relatively low temperatures (e.g., under 250 °C or under 200 °C) can result in such deposition of material 220 and voids 229.

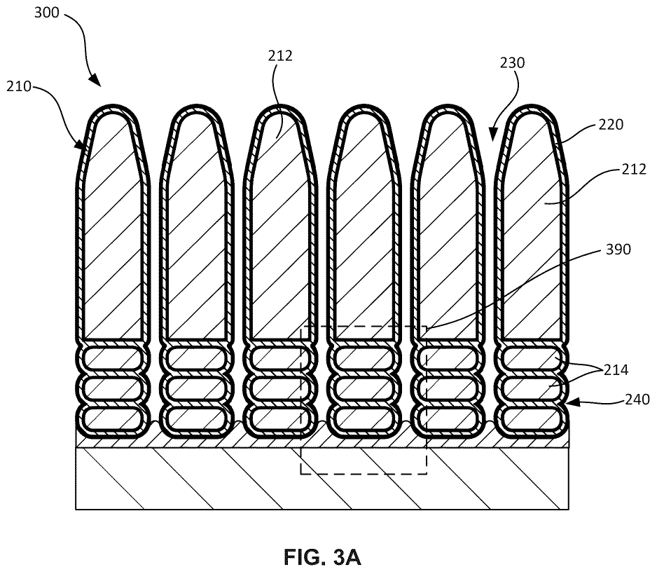

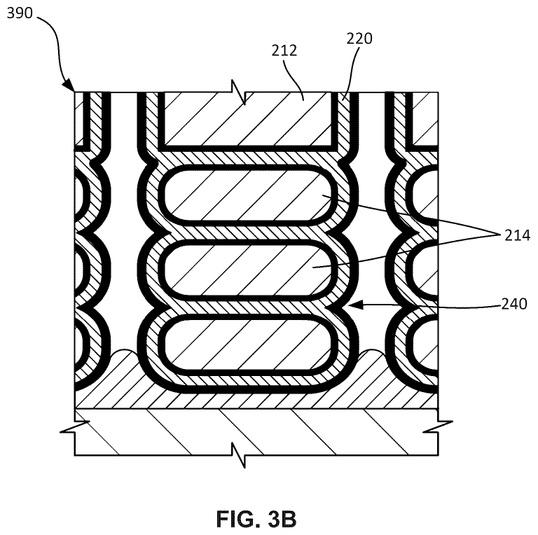

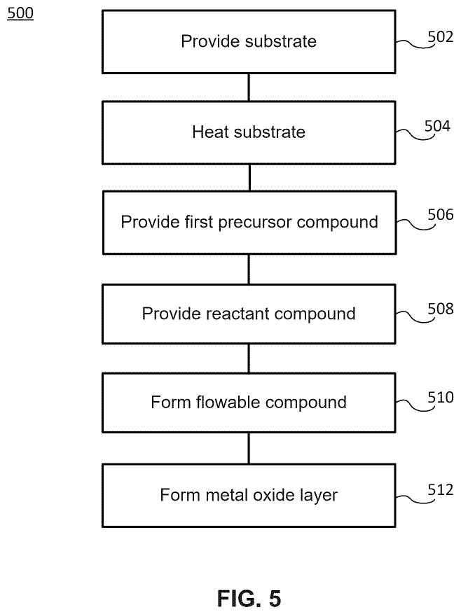

Seams or voids 229 may be undesirable, and thus deposition processes forming a structure without seams or voids (i.e., seamless and/or voidless) may be desired. In various examples, FIG. 5 depicts a method 500 of depositing material on a substrate. With additional reference to FIGS. 3A and 3B, a substrate 210 can be provided (step 502) into a reaction chamber (e.g., reaction chamber 4 in FIG. 1). As discussed herein, substrate 210 can comprise features (vertical posts 212 and/or horizontal ribbons 214) having gap features therebetween, such as vertical gaps 230 and/or horizontal gaps 240. Substrate 210 can be heated (step 504). Heating substrate 210 can occur in preparation for, and/or during, providing precursors/reactants and/or formation of material 220. Substrate 210 can be heated to any suitable temperature, for example, a temperature ranging from 100 °C to 400 °C, a temperature of 200 °C or above and/or 250 °C or above, or a temperature in the range of 250-400 °C or 250-300 °C.

A first precursor compound can be provided (step 506) to the reaction chamber. The first precursor compound can be pulsed from a precursor source and contact substrate 210. The first precursor compound can travel down vertical gaps 230 and into horizontal gaps 240. In various examples, the first precursor compound can comprise a metal oxide precursor. In various examples, the first precursor compound can comprise a metal-oxygen bond. The metal in the first precursor compound can comprise a metal from Group 2 through Group 15 of the periodic table, such as aluminum, zirconium, titanium, and/or tantalum. In various examples, the first precursor compound can comprise an alkyl group coupled/bonded to an oxygen atom.

The first precursor compound can exist and/or be provided as an oligomer (“oligomer,” as used herein, includes dimers, trimers, tetramers, and any other compounds comprising repeating units (i.e., units, which by themselves, would be considered monomers)). For example, the first precursor compound can exist as a dimer or trimer.

In various examples, the first precursor compound can be a compound having a chemical formula of MₓR_{y}(OR′)_{z}, where M is a metal (such as the examples discussed herein), where y+z=3x, and where x is the number of units in the oligomer, i.e., x=1 is a monomer, x=2 is a dimer, x=3 is a trimer, x=4 is a tetramer, etc. For example, x can be 2, y can be 4, and/or z can be 2. R can be any alkyl group comprising from 1-6 carbon atoms. For example, R can comprise a methyl, ethyl, isopropyl, isobutyl, and/or t-butyl group. R′ can be any alkyl group comprising 1-8 carbon atoms or any aryl group comprising a benzene ring and optionally comprising an alkyl attached to the ring. For example, R′ can comprise a methyl, ethyl, isopropyl, tert-butyl, and/or phenyl group.

In various examples, the first precursor compound can comprise dimethylaluminum isopropoxide, diethylaluminum isopropoxide, diisobutylaluminum isopropoxide, di-tert-butylaluminum isopropoxide, dimethylaluminum methoxide, diethylaluminum methoxide, diisobutylaluminum methoxide, di-tert-butylaluminum methoxide, dimethylaluminum ethoxide, diethylaluminum ethoxide, diisobutylaluminum ethoxide, di-tert-butylaluminum ethoxide, dimethylaluminum tert-butoxide, diethylaluminum tert-butoxide, diisobutylaluminum tert-butoxide, di-tert-butylaluminum tert-butoxide, dimethylaluminum sec-butoxide, diethylaluminum sec-butoxide, diisobutylaluminum sec-butoxide, di-tert-butylaluminum sec-butoxide, dimethylaluminum tert-pentoxide, diethylaluminum tert-pentoxide, diisobutylaluminum tert-pentoxide, and/or di-tert-butylaluminum tert-pentoxide. Compounds corresponding to the foregoing including zirconium, titanium, tantalum, hafnium, and/or gallium, e.g., instead of the aluminum atom(s), are also contemplated.

Providing the first precursor compound can comprise any suitable pulse time. For example, the first precursor compound can be pulsed (each time providing the first precursor compound) for a duration of anywhere from 0.1 to 10 seconds, from 1 to 10 seconds, from 0.1 to 0.5 seconds, from 0.5 to 1 seconds, from 1 to 3 seconds, and/or the like.

In various examples, a reactant compound can be provided (step 508) to the reaction chamber. The reactant compound can comprise oxygen. For example, the reactant compound can comprise water (H₂O), an alcohol (e.g., methanol, ethanol, isopropanol, and/or tert-butanol), and/or an aldehyde (e.g., formaldehyde, acetaldehyde, propionaldehyde, butyraldehyde, and/or pivaldehyde).

Providing the reactant compound can comprise any suitable pulse time. For example, the reactant compound can be pulsed (each time providing the reactant compound) for a duration of anywhere from 0.1 to 10 seconds, from 1 to 10 seconds, from 0.1 to 0.5 seconds, from 0.5 to 1 seconds, from 1 to 3 seconds, and/or the like.

Following each pulse of the first precursor compound and/or the reactant compound, there can be a purge step, in which the reaction chamber is purged by a purge gas (e.g., a nonreactive and/or inert gas, such as nitrogen gas, helium, argon, krypton, xenon, and/or the like). For example, following step 506, there can be a purge step, and following step 508, there can be a purge step. During a purge step, the purge gas can be provided from purge gas source 14 to reaction chamber 4 (shown in FIG. 1). A purge gas can be provided (e.g., pulsed) for any suitable duration, such as for a duration of anywhere from 0.1 to 10 seconds, from 1 to 10 seconds, from 0.1 to 0.5 seconds, from 0.5 to 1 seconds, from 1 to 3 seconds, and/or the like.

In various examples, in response to heating substrate 210 (step 504), providing the first precursor compound (step 506), and/or providing the reactant compound (step 508), a flowable compound can be formed (step 510). For example, in response to the first precursor compound being heated by the heated substrate 210, the oligomer of the first precursor compound can at least partially decompose into a smaller oligomer (e.g., a trimer to a dimer) or to a monomer. Thus, step 504 can include heating substrate 210 to a temperature above a decomposition temperature for a respective first precursor compound. For example, a decomposition temperature can comprise a temperature ranging from 100 °C to 400 °C, a temperature of 200 °C or above and/or 250 °C or above, or a temperature in the range of 250-400 °C or 250-300 °C. As another example, with a first precursor compound comprising dimethylaluminum isopropoxide, which can be in the form of a dimer, the dimethylaluminum isopropoxide dimer can decompose to a monomer at a temperature at or above about 250 °C, at or above about 280 °C, or at or above about 300 °C (“about” can mean plus or minus 20 °C or as otherwise defined herein). In response, the decomposed compound (e.g., a monomer dimethylaluminum isopropoxide) can selectively migrate into vertical gaps 230 and/or horizontal gaps 240. For example, the decomposed compound can migrate selectively into the relatively smaller of the gaps (e.g., horizontal gaps 240), before filling relatively larger gaps (e.g., vertical gaps 230). Without being bound by theory, this migration can occur because the decomposed compound can be a smaller compound, thus allowing greater mobility within the smaller horizontal gaps 240, and/or because the flow of the decomposed compound can become at least partially molecular flow (as opposed to viscous flow). In the horizontal gaps 240, the high ratio of surface area to volume therein can facilitate a high probability (or guaranteed, i.e., 100% probability) of interaction between the decomposed compounds and the surface of substrate 210. Thus, the interaction between the decomposed compound and the surfaces can be energetic, facilitating flow of the decomposed compound preferentially into horizontal gaps 240 (e.g., via capillary action).

In various examples, the first precursor compound (in its oligomer form) can form into a larger oligomer (having a greater number of units) before the decomposition discussed herein. For example, monomer and/or oligomers can react in the gas or liquid phase, and/or on the surface of the substrate to produce larger oligomers (i.e., produce oligomers). Such product oligomers can comprise flowable and/or gap-filling properties. As a further example, a dimer of dimethylaluminum isopropoxide (formula Al₂(OiPr)₂Me₄) can react with a monomer of dimethylaluminum isopropoxide (formula Al(OiPr)Me₂) to form a trimer thereof (formula Al₃(OiPr)₃Me₆). The trimer can further react with other monomer or dimer species to form larger oligomers, some of which can have properties (e.g. vapor pressure, molecular weight, ability to perform cross-linking reactions) that enhance flowability and/or gap-filling.

As another example of forming a flowable compound (step 510), without being bound by theory, the first precursor compound with the reactant compound (e.g., water) can form a sol-gel in vertical gaps 230 and/or horizontal gaps 240. The sol-gel can comprise a matrix of metal hydroxide (e.g., aluminum hydroxide), which may be formed by residual and/or retained water molecules in substrate 210. The flowable compound (e.g., comprising a sol-gel) can preferentially flow into vertical gaps 230 and/or horizontal gaps 240. In various examples, the flowable compound can flow into vertical gaps 230 and then preferentially into horizontal gaps 240, thus filling horizontal gaps 240 without seams or voids, before further depositing on the surfaces and/or area/volume of vertical gaps 230. This can facilitate the seamless/voidless filling of horizontal gaps (e.g., as shown in horizontal gaps 240 of structure 300 in FIGS. 3A and 3B).

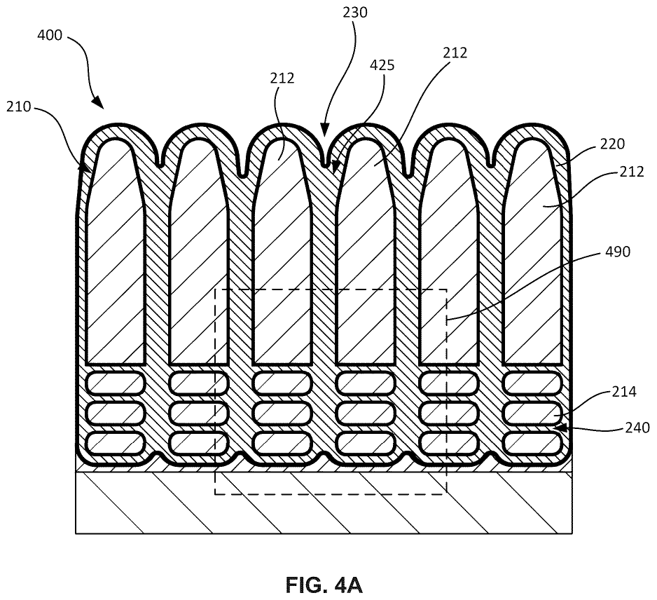

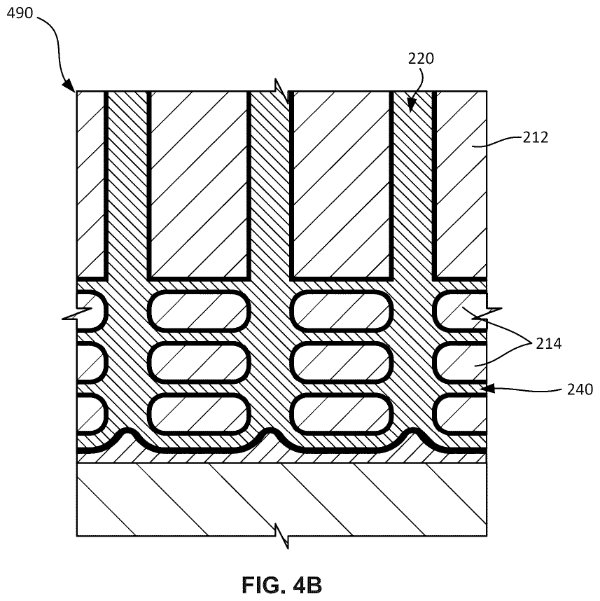

In response to the first precursor compound and/or any resulting compounds (e.g., the decomposed compound and/or sol-gel) migrating into vertical gaps 230 and/or horizontal gaps 240, a metal oxide layer can be formed (step 510) (the metal oxide layer being material 220 in structures of FIGS. 3A-4B). The compound(s) within vertical gaps 230 and/or horizontal gaps 240 may be further decomposed to the metal oxide layer, for example, via the heat provided by the heated substrate 210. For example, the decomposed compound (e.g., a monomer of the first precursor compound) can further decompose (e.g., severing metal-carbon bonds within such compound) to form the metal oxide, and/or the sol-gel comprising a matrix comprising metal hydroxide can further decompose the metal hydroxide to the metal oxide.

In various examples, a reactant compound comprising oxygen may not need to be provided to form the metal oxide layer (i.e., step 508 can be omitted as appropriate). The first precursor compound comprising oxygen may provide sufficient oxygen (the co-reactant) to facilitate formation of the metal oxide layer, in accordance with the examples discussed herein.

The steps of method 500 can be repeated in any combination in any suitable order and/or number to achieve a desired metal oxide layer on substrate 210. For example, horizontal gaps 240 can be filled and a film formed in vertical gaps 230 (e.g., without filling vertical gaps 230), such as structure 300 of FIG. 3A. To also fill vertical gaps 230, as shown in structure 400 of FIG. 4A, the steps of method 500 can be repeated to form the metal oxide layer. The metal oxide layer can be formed without seams or voids, as shown in seamless horizontal gap fill of structure 300 (and close-up view 390 thereof) and seamless vertical gap fill 425 of structure 400 (and close-up view 490 thereof).

The examples of the disclosure described above do not limit the scope of the claimed subject matter, since these are merely examples. The invention is defined by the appended claims and their legal equivalents. Any equivalent embodiments are intended to be within the scope of this disclosure. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

What is claimed is:

1. A method, comprising:
providing a substrate into a reaction chamber, wherein the substrate comprises a vertical gap and a horizontal gap;
heating the substrate within the reaction chamber;
providing a first precursor compound comprising a metal-oxygen bond, wherein the first precursor compound is in the form of an oligomer; and
providing a reactant compound to the reaction chamber, wherein the reactant compound comprises oxygen,
wherein heating the substrate causes decomposition of the oligomer to a decomposed compound and migration of the decomposed compound into the vertical gap and the horizontal gap, wherein the decomposed compound comprises the metal-oxygen bond.

2. The method of claim 1, further comprising forming a metal oxide layer on the substrate.

3. The method of claim 2, wherein the metal oxide layer is substantially seamless.

4. The method of claim 3, wherein a metal element of the metal oxide layer comprises at least one of aluminum, titanium, zirconium, or tantalum.

5. The method of claim 4, wherein the first precursor compound has a chemical formula of MₓR_{y}(OR′)_{z}, wherein M is a metal, wherein y+z=3x, wherein x is the number of units in the oligomer.

6. The method of claim 5, wherein the first precursor compound comprises dimethylaluminum isopropoxide, wherein the dimethylaluminum isopropoxide is in the form of a dimer before the decomposition.

7. The method of claim 6, wherein the metal oxide layer comprises aluminum oxide.

8. The method of claim 4, wherein the first precursor compound further comprises an alkyl group bonded to the oxygen.

9. The method of claim 1, wherein the migration of the decomposed compound into the horizontal gap occurs at least partially via molecular flow.

10. The method of claim 1, wherein the substrate is heated to a temperature greater than 250 °C during the heating step.

11. The method of claim 10, wherein the substrate is heated to a temperature between 250 °C and 400 °C during the heating step.

12. A method, comprising:
heating a substrate within a reaction chamber, the substrate comprising a vertical gap and a horizontal gap;
pulsing a first precursor compound into the reaction chamber, wherein the first precursor compound comprises a metal-oxygen bond, and wherein the first precursor compound is in the form of an oligomer, wherein the heating the substrate comprises heating to a temperature above a decomposition temperature of the oligomer to form a decomposed compound;
pulsing a reactant compound into the reaction chamber, wherein the reactant compound comprises oxygen,
wherein decomposition of the oligomer to the decomposed compound causes migration of the decomposed compound into the vertical gap and the horizontal gap; and
forming a substantially seamless metal oxide layer on the substrate.

13. The method of claim 12, wherein the first precursor compound further comprises an alkyl group bonded to the oxygen.

14. The method of claim 13, wherein a metal element of the metal oxide layer comprises at least one of aluminum, titanium, zirconium, or tantalum.

15. The method of claim 14, wherein the first precursor compound comprises dimethylaluminum isopropoxide.

16. The method of claim 12, wherein the reactant compound comprises water.

17. The method of claim 12, wherein heating the substrate comprises heating the substrate to a temperature greater than 250 °C.

18. A method, comprising:
heating a substrate within a reaction chamber to a temperature greater than 250 °C, the substrate comprising a vertical gap and a horizontal gap;
providing a first precursor compound into the reaction chamber, wherein the first precursor compound comprises a metal-oxygen bond, and wherein the first precursor compound is in the form of an oligomer;
providing a reactant compound into the reaction chamber, wherein the reactant compound comprises water;
forming a flowable compound comprising a metal hydroxide and the metal-oxygen bond in response to providing the reactant compound, wherein the flowable compound migrates into the vertical gap and the horizontal gap; and
forming a substantially seamless metal oxide layer on the substrate.

19. The method of claim 18, wherein the oligomer decomposes to a decomposed compound in response to the first precursor compound contacting the heated substrate.

20. The method of claim 18, wherein the first precursor compound comprises dimethylaluminum isopropoxide.
